(19) United States
(12) Patent Application Publication
(10) Pub. No.: US 2020/0051887 A1
(43) Pub. Date: Feb. 13, 2020

(54) SEMICONDUCTOR DEVICE, PRINTED CIRCUIT BOARD, ELECTRONIC DEVICE, AND IMAGE PICKUP APPARATUS

(71) Applicant: CANON KABUSHIKI KAISHA, Tokyo (JP)

(72) Inventor: Takashi Aoki, Urayasu-shi (JP)

(21) Appl. No.: 16/524,660

(22) Filed: Jul. 29, 2019

(30) Foreign Application Priority Data
Aug. 7, 2018 (JP) 2018-148903
Jul. 17, 2019 (JP) 2019-132188

(51) Int. Cl. H01L 23/367; H05K 1/18; H01L 27/146; H01L 23/498; H01L 23/00

(52) U.S. Cl. CPC H01L 23/3675; H05K 1/181; H01L 24/32; H01L 23/49816; H01L 27/14618

(57) ABSTRACT

A semiconductor device includes a rigid substrate, a plate-like heat dissipating member, and a semiconductor element provided between the rigid substrate and the heat dissipating member and mounted on the rigid substrate. The heat dissipating member includes a first portion that defines a slit or a recess portion. The first portion extends along a first virtual line segment extending from a first side of an outer periphery of a first region that overlaps with the semiconductor element toward an outside of the first region as viewed in a direction perpendicular to a main surface of the heat dissipating member, and a length of the first portion in a direction parallel to the first side is equal to or smaller than a length of the first portion in a direction perpendicular to the first side.

### BACKGROUND OF THE INVENTION

### Field of the Invention

The present invention relates to a structure of a semiconductor device.

### Description of the Related Art

In a semiconductor device including a semiconductor element such as a large-scale integrated circuit: LSI, there is a tendency that the power consumption of the semiconductor device increases accompanied by improvement in the functionality and performance of electronic devices. Therefore, a semiconductor device having a high heat dissipating property is desired. US Patent Application Publication No. 2015/0194389 discloses a semiconductor device including a heat spreader lid. A semiconductor device including a heat dissipating member such as a heat spreader lid has a structure in which the heat dissipating member is fixed to an upper surface of a semiconductor element or an upper surface of a mold resin covering the semiconductor element via an adhesive layer formed from an adhesive. Accompanied by increase in the scale of the electronic device, there is a tendency that the number of terminals of a semiconductor device increases. On the other hand, miniaturization is desired for the semiconductor device, and therefore it is desired that the pitch between terminals is reduced.

In the case where a semiconductor device including a heat dissipating member is exposed to high temperature for soldering to a substrate or where the semiconductor device is driven and thus heat is generated, the semiconductor device is warped due to the difference in linear expansion coefficient between the heat dissipating member and the semiconductor element and a wiring board on which the semiconductor element is mounted. In the case where the semiconductor device is warped, sometimes bonding failure occurs at a terminal of the semiconductor device. Since high reliability is desired for bonding at terminals due to the narrower pitch between the terminals, it is desired that the warpage of the semiconductor device is suppressed as much as possible. There is a room for further improvement in such a semiconductor device.

### SUMMARY OF THE INVENTION

According to one aspect of the present invention, a semiconductor device includes a rigid substrate, a plate-like heat dissipating member, and a semiconductor element provided between the rigid substrate and the heat dissipating member and mounted on the rigid substrate. The heat dissipating member includes a first portion that defines a slit or a recess portion. The first portion extends along a first virtual line segment extending from a first side of an outer periphery of a first region that overlaps with the semiconductor element toward an outside of the first region as viewed in a direction perpendicular to a main surface of the heat dissipating member, and a length of the first portion in a direction parallel to the first side is equal to or smaller than a length of the first portion in a direction perpendicular to the first side.

Further features of the present invention will become apparent from the following description of exemplary embodiments with reference to the attached drawings.

### BRIEF DESCRIPTION OF THE DRAWINGS

FIG. 1 is an explanatory diagram of a digital camera that is an image pickup apparatus serving as an example of an electronic device according to a first exemplary embodiment.

FIG. 2 is a plan view of a semiconductor device according to the first exemplary embodiment.

FIG. 3 is a section view of the semiconductor device taken along a line III-III of FIG. 2.

FIG. 4A is a plan view of a semiconductor device of a modification example.

FIG. 4B is a plan view of a semiconductor device of a modification example.

FIG. 4C is a plan view of a semiconductor device of a modification example.

FIG. 4D is a plan view of a semiconductor device of a modification example.

FIG. 5A is a plan view of a semiconductor device of a modification example.

FIG. 5B is a plan view of a semiconductor device of a modification example.

FIG. 5C is a plan view of a semiconductor device of a modification example.

FIG. 5D is a plan view of a semiconductor device of a modification example.

FIG. 5E is a plan view of a semiconductor device of a modification example.

FIG. 5F is a plan view of a semiconductor device of a modification example.

FIG. 6 is a graph showing simulation results of Example 1 and Comparative Example 1.

FIG. 7 is a graph showing simulation results of Example 2 and Comparative Examples 2A and 2B.

FIG. 8 is a plan view of a semiconductor device according to a second exemplary embodiment.

FIG. 9 is a plan view of a semiconductor device of a modification example.

FIG. 10 is a plan view of a semiconductor device according to a third exemplary embodiment.

FIG. 11A is a section view of the semiconductor device according to the third exemplary embodiment.

FIG. 11B is a section view of the semiconductor device according to the third exemplary embodiment.

FIG. 11C is a section view of the semiconductor device according to the third exemplary embodiment.

FIG. 12 is a plan view of a semiconductor device according to a fourth exemplary embodiment.

FIG. 13 is a plan view of a semiconductor device of a modification example.

FIG. 14 is a plan view of a semiconductor device according to a fifth exemplary embodiment.

### DESCRIPTION OF THE EMBODIMENTS

Exemplary embodiments of the present invention will be described in detail with reference to drawings.

### First Exemplary Embodiment

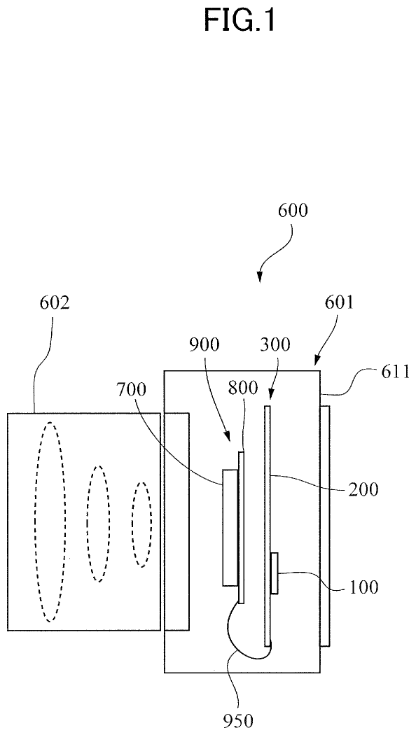

FIG. 1 is an explanatory diagram of a digital camera 600 that is an image pickup apparatus serving as an example of an electronic device according to a first exemplary embodiment. The digital camera 600 that is an image pickup apparatus is a digital camera of a lens-replacing type, and includes a camera body 601. A lens unit 602 that is a lens barrel including a lens is detachably attached to the camera body 601. The camera body 601 includes a casing 611, a printed circuit board 300 and a sensor unit 900 that are disposed inside the casing 611. The printed circuit board 300 and the sensor unit 900 are electrically interconnected by a cable 950.

The sensor unit 900 includes an image sensor 700 that is an image pickup element, and a printed wiring board 800 on which the image sensor 700 is mounted. For example, the image sensor 700 is a complementary metal oxide semiconductor: CMOS image sensor or a charge coupled device: CCD image sensor. The image sensor 700 has a function of converting light incident through the lens unit 602 into an electric signal.

The printed circuit board 300 includes a semiconductor device 100 and a printed wiring board 200 on which the semiconductor device 100 is mounted. The semiconductor device 100 is, for example, a digital signal processor, and has a function of obtaining an electric signal from the image sensor 700, performing processing to correct the obtained electric signal, and generating image data.

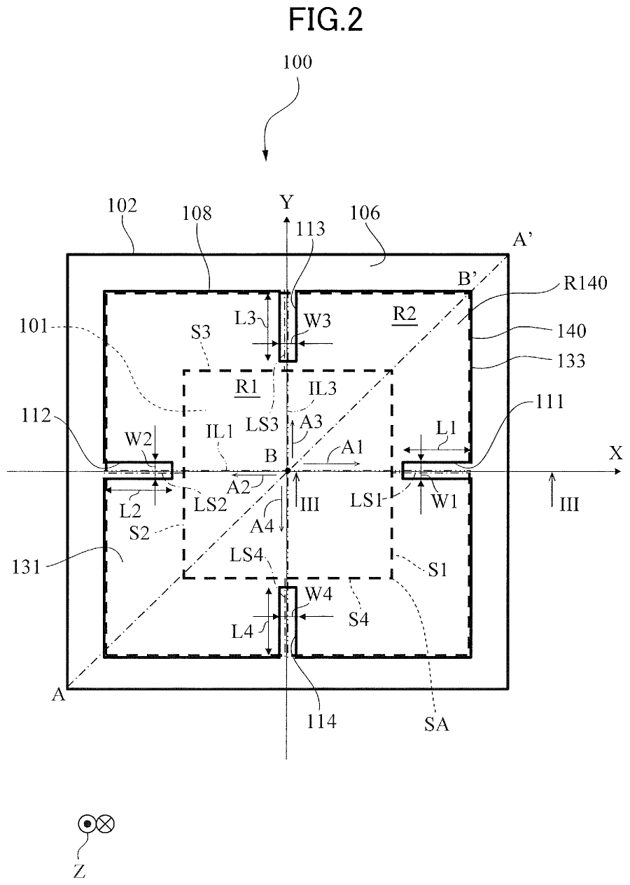

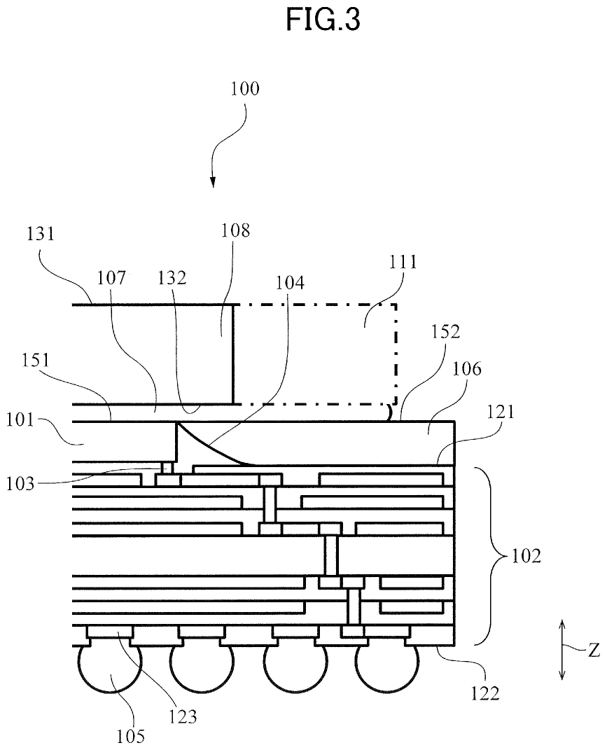

FIG. 2 is a plan view of the semiconductor device 100 according to the first exemplary embodiment. FIG. 3 is a section view of the semiconductor device 100 taken along a line III-III of FIG. 2. The semiconductor device 100 is a semiconductor package of, for example, a ball grid array: BGA. As illustrated in FIG. 3, the semiconductor device 100 includes a semiconductor element 101, a wiring board 102, and a heat dissipating member 108. The semiconductor element 101 is disposed between the wiring board 102 and the heat dissipating member 108, and is mounted on the wiring board 102. The wiring board 102 is a printed wiring board and is a rigid substrate. The wiring board 102 is, for example, a multilayer wiring board formed from glass epoxy resin such as FR-4, or an inorganic substrate such as a ceramic substrate, a glass substrate, or a silicon substrate. The semiconductor element 101 is, for example, a semiconductor chip, and is mounted on a main surface 121 of the wiring board 102 faceup or facedown. In this exemplary embodiment, the semiconductor element 101 is mounted on the main surface 121 facedown. The semiconductor element 101 and the wiring board 102 are electrically and mechanically connected to each other via a bump 103 including solder. The bump 103 is sealed by an underfill 104 formed from a resin material. A plurality of lands 123 arranged in a lattice shape are provided on a main surface 122 of the wiring board 102 opposite to the main surface 121. A solder ball 105 serving as a connection terminal connected to the printed wiring board 200 illustrated in FIG. 1 is attached to each of the plurality of lands 123. When manufacturing the printed circuit board 300 illustrated in FIG. 1, the printed wiring board 200 illustrated in FIG. 1 on which the semiconductor device 100 illustrated in FIG. 3 is mounted is conveyed to the inside of an unillustrated furnace, and is exposed to an atmosphere of a temperature equal to or higher than the melting point of solder. Then, the molten solder is cooled and solidified, and thus the semiconductor device 100 and the printed wiring board 200 are bonded to each other by the solder. The main surface 121 of the wiring board 102 and the underfill 104 are covered by the mold resin 106. An upper surface 151 that is a main surface of the semiconductor element 101 is exposed through the mold resin 106.

The heat dissipating member 108 is formed in a plate-like shape, and has a main surface 131 and a main surface 132 opposite to the main surface 131. The heat dissipating member 108 has a plate-like shape and does not include a fin, and thus has an advantage that the heat dissipating member 108 occupies a smaller space in the casing than a heat sink including a fin does. The main surface 132 of the heat dissipating member 108 is fixed to the upper surface 151 of the semiconductor element 101 and an upper surface 152 of the mold resin 106 via an adhesive layer 107 formed from an adhesive. Since the heat dissipating member 108 is directly fixed to the semiconductor element 101 via the adhesive layer 107, heat generated in the semiconductor element 101 is efficiently transmitted to the heat dissipating member 108. To be noted, although illustration is omitted, the upper surface 151 of the semiconductor element 101 may be covered by the mold resin 106. In this case, the heat dissipating member 108 is fixed to the upper surface of the mold resin 106 via the adhesive layer 107.

The heat dissipating member 108 is preferably formed from a metal material, and among metal materials, the heat dissipating member 108 is preferably formed from copper, which has high thermal conductivity. As the adhesive of the adhesive layer 107, a material having a higher thermal conductivity than air is used. The distance between the heat dissipating member 108 and the semiconductor element 101, that is, the thickness of the adhesive layer 107 is about 30 μm, and heat in the semiconductor element 101 can be quickly transmitted to the heat dissipating member 108. As described above, the semiconductor device 100 has a lamination structure including of three layers in which the main surfaces 131 and 132 of the heat dissipating member 108, the upper surface 151 of the semiconductor element 101, and the main surfaces 121 and 122 of the wiring board 102 are arranged approximately parallel.

FIG. 2 is a diagram illustrating the semiconductor device 100 as viewed in a Z direction perpendicular to the main surface 131 of the heat dissipating member 108. In FIG. 2, two axes passing through the center of the wiring board 102 and perpendicular to each other are denoted by X and Y and the directions thereof are X direction and Y direction. Z direction is a direction perpendicular to the X direction and the Y direction. As illustrated in FIG. 2, as viewed in the Z direction, the outer periphery of the wiring board 102 has a quadrilateral shape, which is a square shape in the present exemplary embodiment. As viewed in the Z direction, the outer periphery of the semiconductor element 101 has a quadrilateral shape, which is a square shape in the present exemplary embodiment. As viewed in the Z direction, an outer peripheral edge 133 of the heat dissipating member 108 has a quadrilateral shape, which is a square shape in the present exemplary embodiment. The shapes of the wiring board 102, the semiconductor element 101, and the heat dissipating member 108 as viewed in the Z direction described above are approximate shapes, and the corners thereof may have round shapes.

As viewed in the Z direction, the heat dissipating member 108 is larger than the semiconductor element 101. That is, as viewed in the Z direction, the heat dissipating member 108 is formed in such a size as to cover the entirety or most of the semiconductor element 101. To be noted, although the heat dissipating member 108 is smaller than the wiring board 102 as viewed in the Z direction as illustrated in FIG. 2, the configuration is not limited to this. The heat dissipating member 108 may be the same size as the wiring board 102 or larger than the wiring board 102 as viewed in the Z direction.

In the present exemplary embodiment, the adhesive layer 107 illustrated in FIG. 3 is in contact with more than 80% of the main surface 132 of the heat dissipating member 108. As a result of this, heat generated in the semiconductor element 101 is efficiently transmitted to the heat dissipating member 108 via the adhesive layer 107. From the viewpoint of thermal conduction, the adhesive layer 107 is preferably in contact with 90% or more of the main surface 132, and is more preferably in contact with the entirety of the main surface 132.

Linear expansion coefficients of the heat dissipating member 108, the semiconductor element 101, and the wiring board 102 are different from one another. For example, the linear expansion coefficient of the heat dissipating member 108 is 17 ppm/° C., the linear expansion coefficient of the semiconductor element 101 is 3 ppm/° C., and the linear expansion coefficient of the wiring board 102 in the case of using a glass epoxy resin is 10 ppm/° C. In the three-layer structure of the heat dissipating member 108, the semiconductor element 101, and the wiring board 102, the linear expansion coefficient of the heat dissipating member 108 is larger than the linear expansion coefficients of the semiconductor element 101 and the wiring board 102.

In addition, Young's modulus that is one of factors that determine bending rigidity will be described. For example, the Young's modulus of the heat dissipating member 108 is 130 GPa, and the Young's modulus of the wiring board 102 is 30 GPa. Therefore, the Young's modulus of the heat dissipating member 108 is higher than the Young's modulus of the wiring board 102. This is because the heat dissipating member 108 needs to be formed from a material having a high thermal conductivity and therefore is formed from a metal material and the wiring board 102 is mainly formed from a resin material. Therefore, when the semiconductor device 100 is exposed to a high temperature when soldering the semiconductor device 100 to the printed wiring board 200 of FIG. 1 or heat is generated in the semiconductor element 101 due to operation thereof, the semiconductor device 100 is warped to have a convex shape toward the heat dissipating member 108. This is because thermal stress F1 generated in the heat dissipating member 108 is larger than thermal stress F2 generated in the semiconductor element 101 and thermal stress F3 generated in the wiring board 102, and the heat dissipating member 108 deforms more than the semiconductor element 101 and the wiring board 102. The thermal stresses F1, F2, and F3 are known to be generally proportional to the product of the linear expansion coefficient, the Young's modulus serving as flexural modulus, and the size of the shape. Therefore, since the linear expansion coefficient and the Young's modulus of the heat dissipating member 108 are larger than those of the semiconductor element 101 and the wiring board 102, the thermal stress F1 is larger than the thermal stress F2 and thermal stress F3.

Therefore, in the present exemplary embodiment, the heat dissipating member 108 is formed in a shape in which the rigidity of the heat dissipating member 108 is relatively low with respect to the wiring board 102 to reduce the thermal stress generated in a high temperature state, and thus the warpage of the semiconductor device 100 is reduced. The shape of the heat dissipating member 108 will be described in detail below. As illustrated in FIG. 2, when the heat dissipating member 108 is viewed in the Z direction, the heat dissipating member 108 can be divided into a first region R1 that overlaps with the semiconductor element 101, and a second region R2 that is further on the outside than the first region R1 and does not overlap with the semiconductor element 101. As viewed in the Z direction, the outer periphery SA of the first region R1 has a shape of the semiconductor element 101, which is a square shape in the present exemplary embodiment. In FIG. 2, the center of the semiconductor element 101, that is, the center of the first region R1 overlaps with the center of the wiring board 102. As viewed in the Z direction, the outer periphery SA of the region R1 includes a first side S1, a second side S2 opposing the first side S1, a third side S3 adjacent to the first side S1 and the second side S2, and a fourth side S4 adjacent to the first side S1 and the second side S2 and opposing the third side S3. The outer peripheral edge 133 of the heat dissipating member 108 serving as the outer periphery of the second region R2 as viewed in the Z direction has a square shape larger than the outer periphery SA. In the present exemplary embodiment, sides of the outer periphery of the first region R1 are approximately parallel to the sides of the outer peripheral edge 133 of the heat dissipating member 108.

The heat dissipating member 108 includes a first portion 111 that defines a slit or a recess portion, a second portion 112 that defines a slit or a recess portion, a third portion 113 that defines a slit or a recess portion, and a fourth portion 114 that defines a slit or a recess portion. The portions 111 to 114 are independent from one another. The portions 111 to 114 are each a portion that defines an empty space where the metal material making up the heat dissipating member 108 is not present. In the present exemplary embodiment, the portions 111 to 114 are each a portion that defines a slit. Here, a slit is a cutout that penetrates through the heat dissipating member 108 in the Z direction. The portions 111 to 114 may be continuous or not continuous with the outer peripheral edge 133 of the heat dissipating member 108. In the present exemplary embodiment, the portions 111 to 114 are continuous with the outer peripheral edge 133. That is, the portions 111 to 114 extend to the outer peripheral edge 133 of the heat dissipating member 108. As viewed in the Z direction, part or the entirety of the first portion 111, the entirety in the present exemplary embodiment, is positioned in the region R2. As viewed in the Z direction, part or the entirety of the second portion 112, the entirety in the present exemplary embodiment, is positioned in the region R2. As viewed in the Z direction, part or the entirety of the third portion 113, the entirety in the present exemplary embodiment, is positioned in the region R2. As viewed in the Z direction, part or the entirety of the fourth portion 114, the entirety in the present exemplary embodiment, is positioned in the region R2. To be noted, although the portions 111 to 114 are each illustrated in a rectangular shape in FIG. 2, for example, corners of each of the portions 111 to 114 may be formed in round shapes.

As viewed in the Z direction, the portions 111 to 114 do not extend in the first region R1 and only extend in the second region R2. When a current flows in a circuit in the semiconductor element 101, a return current is generated in a portion of the region R1 opposing the semiconductor element 101 in the heat dissipating member 108. Since the portions 111 to 114 that each defines a slit are not present in the region R1, a path for the return current can be secured, and thus radiation of an electromagnetic noise can be reduced. In addition, warpage of the semiconductor device 100 can be efficiently reduced. The reason for this will be described below. Whereas the heat dissipating member 108 is present on the mold resin 106 in the second region R2, the heat dissipating member 108 is present on the semiconductor element 101 in the first region R1. The mold resin 106 has a smaller Young's modulus than the semiconductor element 101. Therefore, the warpage of the semiconductor device 100 caused by the thermal stress generated in the heat dissipating member 108 is larger in the second region R2 than in the first region R1. Therefore, the portions 111 to 114 that each defines a slit or a recess portion is provided in the second region R2 to reduce the thermal stress generated in the heat dissipating member 108, and thus the warpage of the semiconductor device 100 can be reduced.

As viewed in the Z direction, the first portion 111 extends along a first virtual line segment LS1 extending from the first side S1 of the outer periphery SA of the first region R1 to the outside of the first region R1. In addition, as viewed in the Z direction, the second portion 112 extends along a second virtual line segment LS2 extending from the second side S2 of the outer periphery SA of the first region R1 to the outside of the first region R1.

As viewed in the Z direction, the slit defined by the first portion 111 is positioned on a virtual straight line IL1 passing through the first side S1 of the outer periphery SA of the first region R1 and extending from the outer peripheral edge 133 of the heat dissipating member 108 to the inside of the first region R1. The virtual straight line IL1 is also a virtual straight line passing through the second side S2 of the outer periphery SA of the first region R1 and extending to the inside of the first region R1. As viewed in the Z direction, the slit defined by the second portion 112 is positioned on the virtual straight line IL1. That is, as viewed in the Z direction, the first portion 111 and the second portion 112 are positioned on one straight line, that is, the same virtual straight line IL1.

As viewed in the Z direction, the third portion 113 extends along a third virtual line segment LS3 extending from the third side S3 of the outer periphery SA of the first region R1 to the outside of the first region R1. In addition, as viewed in the Z direction, the fourth portion 114 extends along a fourth virtual line segment LS4 extending from the fourth side S4 of the outer periphery SA of the first region R1 to the outside of the first region R1.

As viewed in the Z direction, the slit defined by the third portion 113 is positioned on a virtual straight line IL3 passing through the third side S3 of the outer periphery SA of the first region R1 and extending from the outer peripheral edge 133 of the heat dissipating member 108 to the inside of the first region R1. The virtual straight line IL3 is also a virtual straight line passing through the fourth side S4 of the outer periphery SA of the first region R1 and extending to the inside of the first region R1. As viewed in the Z direction, the slit defined by the fourth portion 114 is positioned on the virtual straight line IL3. That is, as viewed in the Z direction, the third portion 113 and the fourth portion 114 are positioned on one straight line, that is, the same virtual straight line IL3.

A length W1 of the first portion 111 in a direction parallel to the first side S1 is equal to or smaller than a length L1 thereof in a direction perpendicular to the first side S1, that is, W1≤L1 holds. A length W2 of the second portion 112 in a direction parallel to the second side S2 is equal to or smaller than a length L2 thereof in a direction perpendicular to the second side S2, that is, W2≤L2 holds. A length W3 of the third portion 113 in a direction parallel to the third side S3 is equal to or smaller than a length L3 thereof in a direction perpendicular to the third side S3, that is, W3≤L3 holds. A length W4 of the fourth portion 114 in a direction parallel to the fourth side S4 is equal to or smaller than a length L4 thereof in a direction perpendicular to the fourth side S4, that is, W4≤L4 holds. In the present exemplary embodiment, W1=W2=W3=W4 and L1=L2=L3=L4 hold. Here, the lengths W1 to W4 are preferably equal to or larger than 2% of the length of the heat dissipating member 108 in a W direction. More preferably, the lengths W1 to W4 are equal to or larger than 5% of the length of the heat dissipating member 108 in the W direction. That is, in the case where the length of the heat dissipating member 108 in the W direction is 15 mm, the lengths W1 to W4 are preferably 0.3 mm or larger and more preferably 0.75 mm or larger. In addition, the lengths L1 to L4 are preferably equal to or smaller than 50% of the length of the heat dissipating member 108 in an L direction. This is because there is a possibility that the mechanical strength of the heat dissipating member 108 is degraded when the lengths L1 to L4 exceed 50% of the length of the heat dissipating member 108 in the L direction. More preferably, the lengths L1 to L4 is equal to or smaller than 20% of the length of the heat dissipating member 108 in the L direction. That is, in the case where the length of the heat dissipating member 108 in the L direction is 15 mm, the lengths L1 to L4 are preferably 7.5 mm or smaller and more preferably 3.0 mm or smaller.

The first portion 111 preferably defines, as the slit, an elongated hole extending linearly in a longitudinal direction along the virtual straight line IL1 as viewed in the Z direction. The first portion 111 is also a portion that defines a cutout extending from the outer peripheral edge 133 of the heat dissipating member 108 toward the first side S1 as viewed in the Z direction. That is, as a result of the first portion 111 being continuous with the outer peripheral edge 133 of the heat dissipating member 108, the slit defined by the first portion 111 is a cutout opening in the outer peripheral edge 133.

The second portion 112 preferably defines, as the slit, an elongated hole extending linearly in a longitudinal direction along the virtual straight line IL1 as viewed in the Z direction. The second portion 112 is also a portion that defines a cutout extending from the outer peripheral edge 133 of the heat dissipating member 108 toward the second side S2 as viewed in the Z direction. That is, as a result of the second portion 112 being continuous with the outer peripheral edge 133 of the heat dissipating member 108, the slit defined by the second portion 112 is a cutout opening in the outer peripheral edge 133.

The third portion 113 preferably defines, as the slit, an elongated hole extending linearly in a longitudinal direction along the virtual straight line IL3 as viewed in the Z direction. The third portion 113 is also a portion that defines a cutout extending from the outer peripheral edge 133 of the heat dissipating member 108 toward the third side S3 as viewed in the Z direction. That is, as a result of the third portion 113 being continuous with the outer peripheral edge 133 of the heat dissipating member 108, the slit defined by the third portion 113 is a cutout opening in the outer peripheral edge 133.

The fourth portion 114 preferably defines, as the slit, an elongated hole extending linearly in a longitudinal direction along the virtual straight line IL3 as viewed in the Z direction. The fourth portion 114 is also a portion that defines a cutout extending from the outer peripheral edge 133 of the heat dissipating member 108 toward the fourth side S4 as viewed in the Z direction. That is, as a result of the fourth portion 114 being continuous with the outer peripheral edge 133 of the heat dissipating member 108, the slit defined by the fourth portion 114 is a cutout opening in the outer peripheral edge 133.

According to the present exemplary embodiment, by providing the first portion 111 in the heat dissipating member 108, the thermal stress of the heat dissipating member 108 in the Y direction can be reduced, and the rigidity of the heat dissipating member 108 in the Y direction can be reduced. Further, by providing the second portion 112 in the heat dissipating member 108, the thermal stress of the heat dissipating member 108 in the Y direction can be reduced, and the rigidity of the heat dissipating member 108 in the Y direction can be effectively reduced. That is, although it suffices when only the first portion 111 is provided, the rigidity of the heat dissipating member 108 in the Y direction can be more effectively reduced by further providing the second portion 112.

In addition, according to the present exemplary embodiment, by providing the third portion 113 in the heat dissipating member 108, the thermal stress of the heat dissipating member 108 in the X direction can be reduced, and the rigidity of the heat dissipating member 108 in the X direction can be reduced. Further, by providing the fourth portion 114 in the heat dissipating member 108, the thermal stress of the heat dissipating member 108 in the X direction can be reduced, and the rigidity of the heat dissipating member 108 in the X direction can be reduced.

In addition, since the two portions 111 and 112 are present on the virtual straight line ILL the rigidity of the heat dissipating member 108 in the Y direction can be effectively reduced. In addition, since the two portions 113 and 114 are present on the virtual straight line IL3, the rigidity of the heat dissipating member 108 in the X direction can be effectively reduced.

As described above, the portions 111 to 114 function as stress releasing portions in the heat dissipating member 108. As a result of this, the rigidity of the heat dissipating member 108 can be relatively reduced with respect to the wiring board 102, and thus the warpage of the semiconductor device 100 when the semiconductor device 100 is heated or the semiconductor element 101 generates heat can be reduced. In addition, as a result of 80% or more of the main surface 132 of the heat dissipating member 108 being in contact with the adhesive layer 107, the heat generated in the semiconductor element 101 can be effectively transmitted to the heat dissipating member 108.

Further, the first portion 111, the second portion 112, the third portion 113, and the fourth portion 114 are respectively formed to satisfy W1≤L1, W2≤L2, W3≤L3, and W4≤L4. That is, the portions 111 to 114 radially extend toward the first region R1. Therefore, the heat generated in the semiconductor element 101 radially diffuses from the first region R1 toward the outer peripheral edge 133 of the heat dissipating member 108 without being blocked by the portions 111 to 114. As described above, the portions 111 to 114 are radially formed such that flow of heat is not blocked, and therefore heat can be effectively dissipated to the outside from the heat dissipating member 108 and the heat dissipating property can be secured.

In addition, the slits defined by the portions 111 to 114 are cutouts extending to the outer peripheral edge 133. Since the warpage of the semiconductor device 100 caused by the thermal stress generated in the heat dissipating member 108 is larger at a position closer to the peripheral edge of the heat dissipating member 108, by employing such a configuration, the thermal stress can be effectively released, and the warpage of the semiconductor device 100 can be effectively reduced.

From the viewpoint of reducing the rigidity of the heat dissipating member 108 and improving the heat dissipating property of the heat dissipating member 108, the portions 111 and 112 are preferably positioned on the virtual straight line IL1 passing through the center of the first region R1 as illustrated in FIG. 2. Similarly, the portions 113 and 114 are preferably positioned on the virtual straight line IL3 passing through the center of the first region R1. When the heat dissipating member 108 is viewed in the Z direction, the center of a surrounded region R140 surrounded by the shortest surrounding line 140 that surrounds the heat dissipating member 108 is denoted by B. In addition, a corner portion of the surrounded region R140 is denoted by B′. The portions 111 to 114 extend in respective directions A1, A2, A3, and A4 from the center B toward the surrounding line 140. As a result of this, the warpage of the semiconductor device 100 can be efficiently reduced while securing a good heat dissipating property. To be noted, as viewed in the Z direction, the surrounding line 140 coincides with the outer peripheral edge 133 of the heat dissipating member 108.

In addition, from the viewpoint of reducing the rigidity of the heat dissipating member 108 and improving the heat dissipating property of the heat dissipating member 108, the first portion 111 preferably extends in the longitudinal direction thereof perpendicular to the first side S1. Similarly, the second portion 112 preferably extends in the longitudinal direction thereof perpendicular to the second side S2, the third portion 113 preferably extends in the longitudinal direction thereof perpendicular to the third side S3, and the fourth portion 114 preferably extends in the longitudinal direction thereof perpendicular to the fourth side S4. That is, it is preferable that W1<L1, W2<L2, W3<L3, and W4<L4 are preferable.

The area of the adhesive layer 107 as viewed in the Z direction affects the heat dissipating property and magnitude of the warpage of the semiconductor device 100. Therefore, it is desired that the area of the adhesive layer 107 is managed within a certain range. In the present exemplary embodiment, the portions 111 to 114 define slits, and therefore the presence/absence of the adhesive layer 107 can be recognized through the slits. Therefore, whether or not the adhesive layer 107 spreads to at least the portions 111 to 114 can be easily inspected, and as a result, variations in the heat dissipating property and the magnitude of the warpage between individual products can be reduced. To be noted, part of the adhesive layer 107 may overlap with the slits defined by the portions 111 to 114.

To be noted, although the first portion 111 is a straight inner wall in FIG. 3, the same effect can be achieved also in the case where the first portion is an inner wall of a tapered shape or a step shape. The same applies to the second portion 112, the third portion 113, and the fourth portion 114.

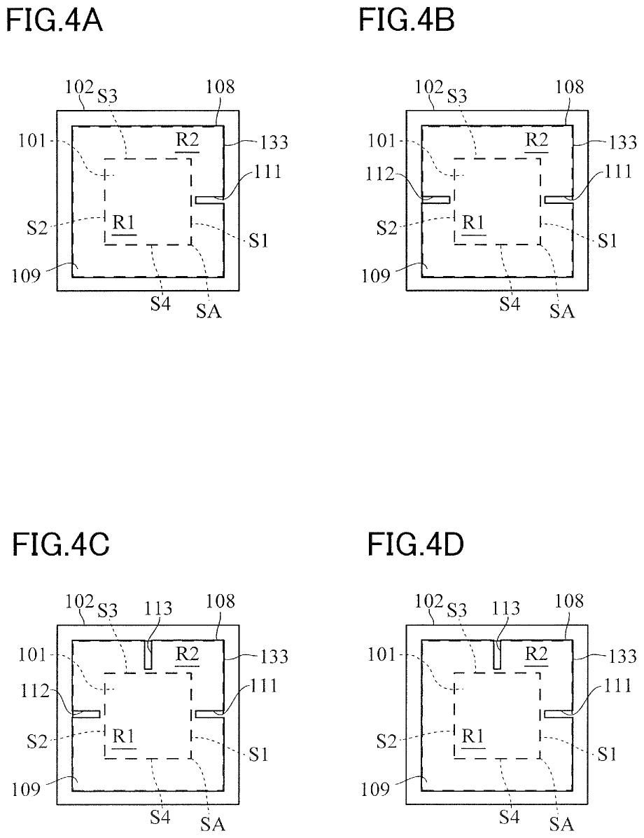

Although it is preferable that the portions 111 to 114 are formed in the heat dissipating member 108, part of these may be omitted. FIGS. 4A to 4D are each a plan view of a semiconductor device of a modification example. For example, as illustrated in FIG. 4A, a configuration in which the heat dissipating member 108 includes the portion 111 but does not include the portions 112 to 114 may be employed. In addition, as illustrated in FIG. 4B, a configuration in which the heat dissipating member 108 includes the portions 111 and 112 but does not include the portions 113 and 114 may be employed. In addition, as illustrated in FIG. 4C, a configuration in which the heat dissipating member 108 includes the portions 111 to 113 but does not include the portion 114 may be employed. In addition, as illustrated in FIG. 4D, a configuration in which the heat dissipating member 108 includes the portions 111 and 113 but does not include the portions 112 and 114 may be employed.

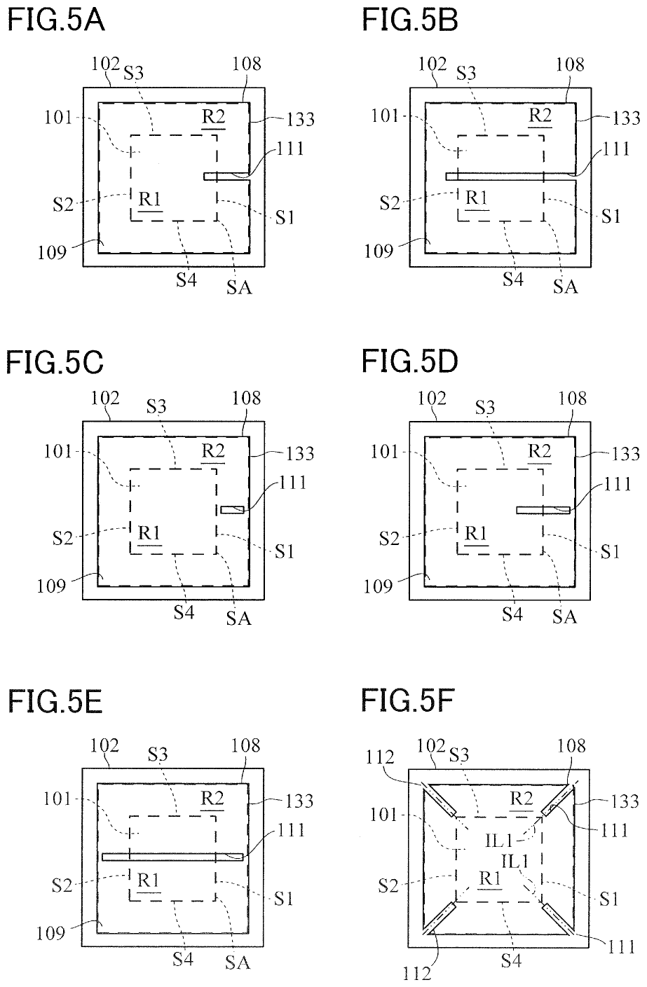

In addition, FIGS. 5A to 5F are plan views of semiconductor devices of other modification examples. As illustrated in FIG. 5A, the portion 111 may be positioned to be present in both of the regions R1 and R2. As illustrated in FIG. 5B, the portion 111 may be positioned to intersect with both of the side S1 and the side S2 opposing the side S2. In addition, a configuration in which the portion 111 does not extend from the outer peripheral edge 133 of the heat dissipating member 108 toward the first region R1 may be employed, that is, the portion 111 does not have to be continuous with the outer peripheral edge 133. In this case, for example, the portion 111 may be positioned to be present only in the region R2 as illustrated in FIG. 5C. In addition, for example, the portion 111 may be positioned to be present in both of the regions R1 and R2 as illustrated in FIG. 5D. Further, for example, the portion 111 may be positioned to intersect with both of the sides S1 and S2 as illustrated in FIG. 5E. In addition, the portion 111 may be positioned on a virtual straight line intersecting with the side S1, and as illustrated in FIG. 5F, the virtual straight line IL1 on which the portion 111 is positioned does not have to be perpendicular to the side S1. In addition, as in the example illustrated in FIG. 5F, a plurality of portions 111 may be provided. For example, two portions 111 may be provided. Although description has been given regarding the portion 111, the other portions 112 to 114 may be configured as illustrated in FIGS. 5A to 5F. In the example of FIG. 5F, a plurality of the portions 112, for example, two portions 112 are provided.

### EXAMPLE 1

The warpage of the semiconductor device 100 described above and illustrated in FIGS. 2 and 3 at a temperature of 250° C. was simulated. Structure analysis software available from Ansys was used as a simulator. The dimensions of the semiconductor element 101 were set to a length of 10 mm, a width of 10 mm, and a thickness of 0.1 mm. The dimensions of the wiring board 102 were set to a length of 18 mm, a width of 18 mm, and a thickness of 0.45 mm. The dimensions of the heat dissipating member 108 were set to a length of 15 mm, a width of 15 mm, and a thickness of 0.4 mm. The linear expansion coefficient of the semiconductor element 101 was set to 3 ppm/° C., the linear expansion coefficient of the wiring board 102 was set to 10 ppm/° C., and the linear expansion coefficient of the heat dissipating member 108 was set to 17 ppm/° C. The Young's modulus of the semiconductor element 101 was set to 400 GPa, the Young's modulus of the wiring board 102 was set to 30 GPa, and the Young's modulus of the heat dissipating member 108 was set to 130 GPa. The dimensions of the slits defined by the portions 111 to 114 were set to L1, L2, L3, L4=2.5 mm and W1, W2, W3, and W4=1.0 mm.

### COMPARATIVE EXAMPLE 1

For comparison, the warpage of a semiconductor device including a heat dissipating member not provided with a slit at a temperature of 250° C. was also simulated. The same simulator as Example 1 was used. In this simulation, the same parameter values as in Example 1 except for the parameter values of the portions 111 to 114 were used for the semiconductor device of Comparative Example 1.

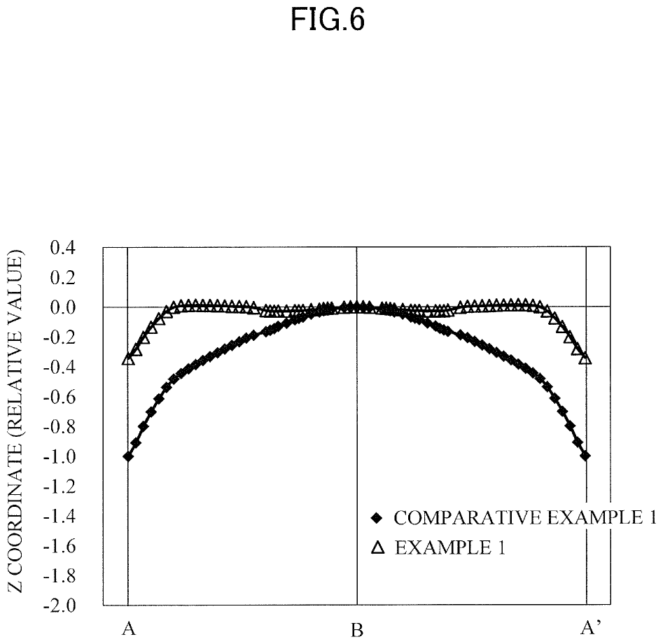

FIG. 6 is a graph showing simulation results of Example 1 and Comparative Example 1. In FIG. 6, values of warpage of the semiconductor device in a section on a straight line connecting positions A and A′ of opposing corners of the wiring board 102 illustrated in FIG. 2 are plotted. The values of warpage are relative values with respect to the value at the position A of the wiring board of Comparative Example 1. The warpage value of Example 1 at the position A is 0.34, and it can be seen that the warpage is reduced by 66% as compared with Comparative Example 1.

### EXAMPLE 2

Next, the heat dissipating property of the semiconductor device 100 was simulated. Thermal fluid analysis software available from Ansys was used as the simulator. The dimensions of the semiconductor device 100 were set to the same values as in Example 1. The thermal conductivity of the heat dissipating member 108 was set to 398 W/mK, and heat flux from the semiconductor element 101 to the heat dissipating member 108 was set to 1 W.

### COMPARATIVE EXAMPLE 2A AND COMPARATIVE EXAMPLE 2B

Simulation was also performed for a case where the slit serving as an empty space is not provided as Comparative Example 2A and a case where the length L1 of the slit is smaller than the length W1, in which L1 is 1.0 mm and W1 is 10 mm, as Comparative Example 2B. To be noted, in Comparative Example 2B, the relationships between the lengths L2 to L4 and the lengths W2 to W4 of the other slits were set to be the same as that of L1 and W1. That is, L2, L3, and L4 were set to 1.0 mm and W2, W3, and W4 were set to 10 mm.

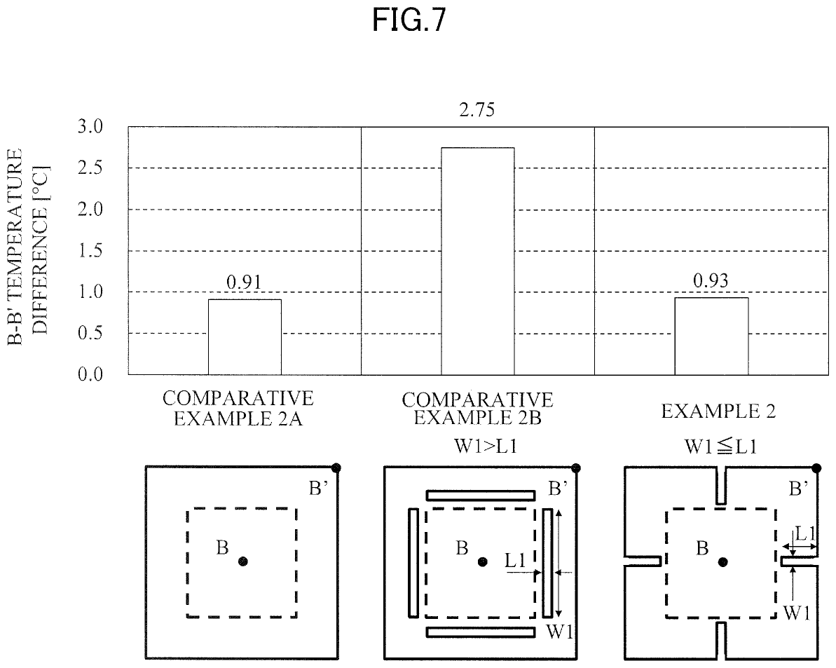

FIG. 7 is a graph showing simulation results of Example 2 and Comparative Examples 2A and 2B. FIG. 7 shows temperature difference between the center B and the corner portion B′ of the surrounded region R140 illustrated in FIG. 2. The temperature difference of Example 2 is 0.93° C., which is hardly different from the temperature difference of 0.91° C. of Comparative Example 2A including just a flat plate as a heat dissipating member. The difference between the values of Example 2 and Comparative Example 2A is 0.02° C. In contrast, whereas the temperature difference of Comparative Example 2B is 2.75° C., the temperature difference of Example 2 is 0.93° C., and it can be seen that the heat dissipating property is better in Example 2. As described above, in Example 2, as a result of setting the dimensions such that W1≤L1, W2≤L2, W3≤L3, and W4≤L4 are satisfied, heat is sufficiently diffused to the outer peripheral edge 133 of the heat dissipating member 108, and a heat dissipating property equivalent to that of Comparative Example 2A not provided with a slit is secured.

### Second Exemplary Embodiment

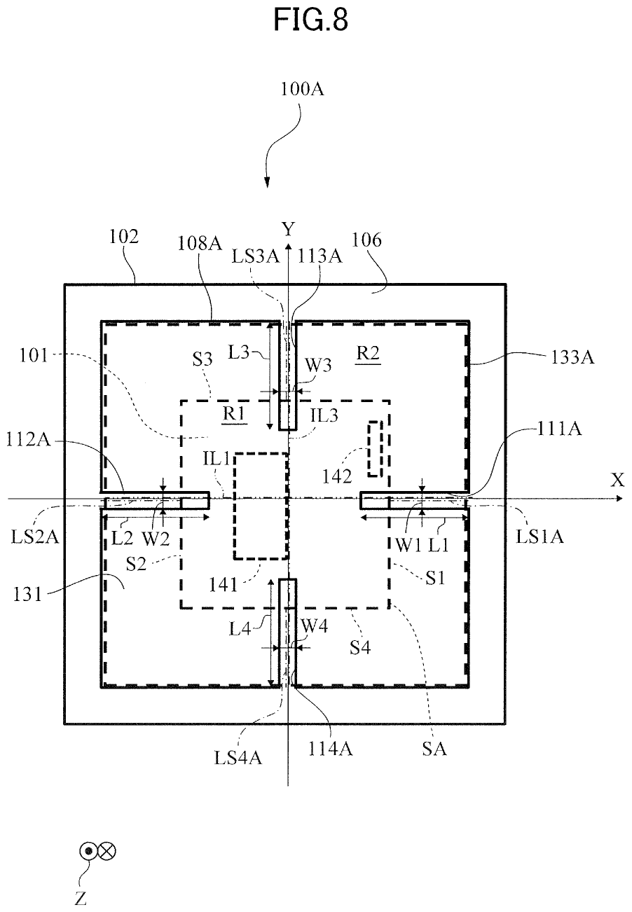

A semiconductor device of a second exemplary embodiment will be described. FIG. 8 is a plan view of a semiconductor device 100A according to the second exemplary embodiment. To be noted, the same elements as in the exemplary embodiment described above will be denoted by the same reference signs and detailed description thereof will be omitted.

A semiconductor device 100A is, for example, a digital signal processor similarly to the first exemplary embodiment. The semiconductor device 100A includes the wiring board 102, a heat dissipating member 108A, and the semiconductor element 101 disposed between the wiring board 102 and the heat dissipating member 108A. The semiconductor element 101 is mounted on the wiring board 102, and is covered by the mold resin 106 with an upper surface thereof exposed. The heat dissipating member 108A is fixed to the upper surface of the semiconductor element 101 and the upper surface of the mold resin 106 via an adhesive layer.

Similarly to the first exemplary embodiment, the heat dissipating member 108A includes a first portion 111A that defines a slit, a second portion 112A that defines a slit, a third portion 113A that defines a slit, and a fourth portion 114A that defines a slit. The portions 111A to 114A are independent from one another. The first portion 111A and the second portion 112A are arranged on one straight line, that is, on the same virtual straight line IL1. The third portion 113A and the fourth portion 114A are arranged on one straight line, that is, on the same virtual straight line IL3.

As viewed in the Z direction, the first portion 111A extends along a first virtual line segment LS1A extending from the first side S1 of the outer periphery SA of the first region R1 toward the outside of the first region R1. In addition, as viewed in the Z direction, the second portion 112A extends along a second virtual line segment LS2A extending from the second side S2 of the outer periphery SA of the first region R1 toward the outside of the first region R1.

As viewed in the Z direction, the third portion 113A extends along a third virtual line segment LS3A extending from the third side S3 of the outer periphery SA of the first region R1 toward the outside of the first region R1. In addition, as viewed in the Z direction, the fourth portion 114A extends along a fourth virtual line segment LS4A extending from the fourth side S4 of the outer periphery SA of the first region R1 toward the outside of the first region R1.

The portions 111A to 114A are each disposed to be present in both of the first region R1 and the second region R2. The portions 111A to 114A may be formed such that W1≤L1, W2≤L2, W3≤L3, and W4≤L4 are satisfied similarly to the first exemplary embodiment, but it is preferable that W1<L1, W2<L2, W3<L3, and W4<L4 are satisfied. In addition, the portions 111A to 114A preferably extend to an outer peripheral edge 133A of the heat dissipating member 108A similarly to the first exemplary embodiment.

The semiconductor element 101 includes an image processing circuit 141 and an interface circuit 142 that generate much heat. For example, the interface circuit 142 is an interface circuit that communicates with an unillustrated memory. The image processing circuit 141 and the interface circuit 142 consume relatively more power per unit area than unillustrated other circuits, and therefore the temperature thereof easily rises.

In the second exemplary embodiment, the portions 111A to 114A that define empty spaces are disposed so as not to overlap with the image processing circuit 141 and the interface circuit 142 that generate much heat as viewed in the Z direction. As a result of this, the thermal resistance between the image processing circuit 141 and the interface circuit 142 that generate much heat and the heat dissipating member 108A can be reduced. Therefore, the heat dissipating property of the semiconductor device 100A can be improved.

The heat dissipating member 108A may be configured as modification examples illustrated in FIGS. 4A to 5F described above.

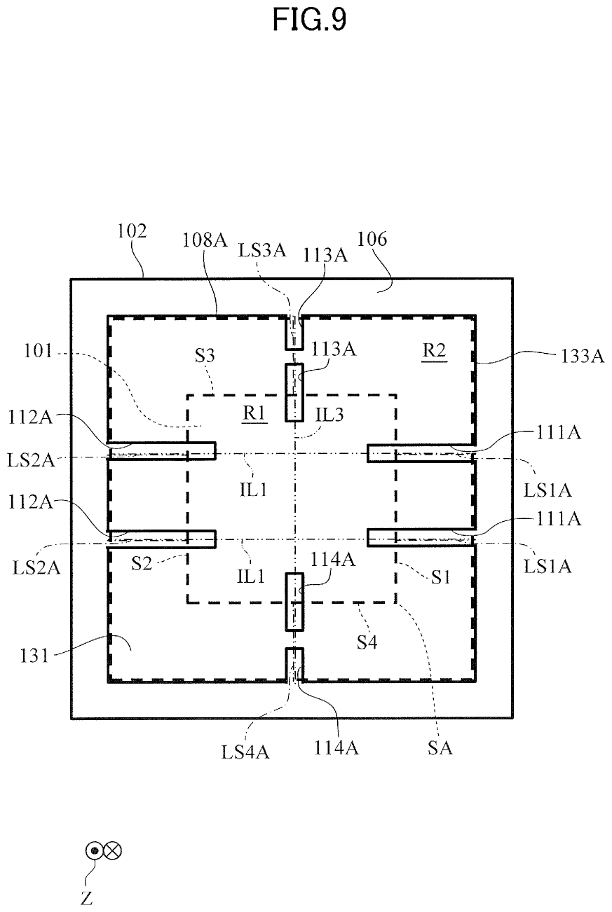

FIG. 9 is a plan view of a semiconductor device of yet another modification example. As illustrated in FIG. 9, the heat dissipating member 108A may include each of the portions 111A to 114A, which defines a slit, in a plural number.

In this case, as illustrated in FIG. 9, the plurality of portions 111A may be respectively disposed along a plurality of virtual line segments LS1A. In addition, the plurality of portions 112A may be respectively disposed along a plurality of virtual line segments LS2A.

In addition, it is preferable that one or more of the plurality of portions 111A is continuous with the outer peripheral edge 133A as viewed in the Z direction. In addition, it is preferable that one or more of the plurality of portions 112A is continuous with the outer peripheral edge 133A as viewed in the Z direction.

In addition, in this case, the plurality of portions 113A may be disposed along one virtual line segment LS3A as illustrated in FIG. 9. In addition, the plurality of portions 114A may be disposed along one virtual line segment LS4A. The plurality of portions 113A and the plurality of portions 114A are preferably arranged on one straight line, that is, on the virtual straight line IL3.

In addition, one of the plurality of portions 113A is preferably continuous with the outer peripheral edge 133A as viewed in the Z direction. In addition, one of the plurality of portions 114A is preferably continuous with the outer peripheral edge 133A as viewed in the Z direction.

Since the portions 111A to 114A are each provided in a plural number, arrangement in which each slit does not overlap with a circuit that generates much heat can be employed even in the case where multiple circuits that generate much heat are provided.

### Third Exemplary Embodiment

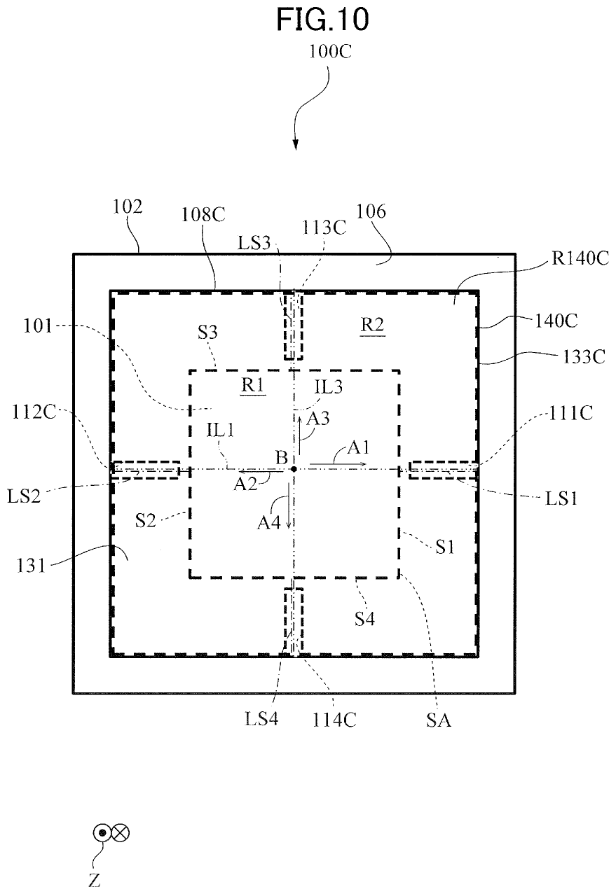

A semiconductor device of a third exemplary embodiment will be described. FIG. 10 is a plan view of a semiconductor device 100C according to the third exemplary embodiment. To be noted, the same elements as in the exemplary embodiments described above will be denoted by the same reference signs and detailed description thereof will be omitted.

The semiconductor device 100C includes the wiring board 102, a heat dissipating member 108C, and the semiconductor element 101 disposed between the wiring board 102 and the heat dissipating member 108C. The semiconductor element 101 is mounted on the wiring board 102, and is covered by the mold resin 106 with an upper surface thereof exposed. The heat dissipating member 108C is fixed to the upper surface of the semiconductor element 101 and the upper surface of the mold resin 106 via an adhesive layer.

The heat dissipating member 108C includes a first portion 111C, a second portion 112C, a third portion 113C, and a fourth portion 114C that each defines an empty space. The portions 111C to 114C are independent from one another. The shape and position of each of the portions 111C to 114C as viewed in the Z direction are the same as those of the portions 111 to 114 of the first exemplary embodiment. That is, the portions 111C to 114C satisfy W1≤L1, W2≤L2, W3≤L3, and W4≤L4 similarly to the first exemplary embodiment. The portions 111C to 114C preferably satisfy W1<L1, W2<L2, W3<L3, and W4<L4. In addition, the portions 111C to 114C preferably extend to an outer peripheral edge 133C of the heat dissipating member 108C similarly to the first exemplary embodiment.

Whereas the portions 111 to 114 illustrated in FIG. 2 and described in the first exemplary embodiment are each a portion defining a slit, the portions 111C to 114C of the third exemplary embodiment are each a portion defining a recess portion, for example, a groove. That is, whereas the portions 111 to 114 of the first exemplary embodiment are each a portion defining an empty space penetrating through the heat dissipating member 108 in the Z direction, the portions 111C to 114C of the third exemplary embodiment do not penetrate through the heat dissipating member 108C in the Z direction. That is, the portions 111C to 114C are each a portion defining an empty space recessed with a thin portion remaining. Although it is preferable that the empty space is a slit as in the first exemplary embodiment or the second exemplary embodiment for each portion to act as a stress releasing portion, the empty space may be a recess portion.

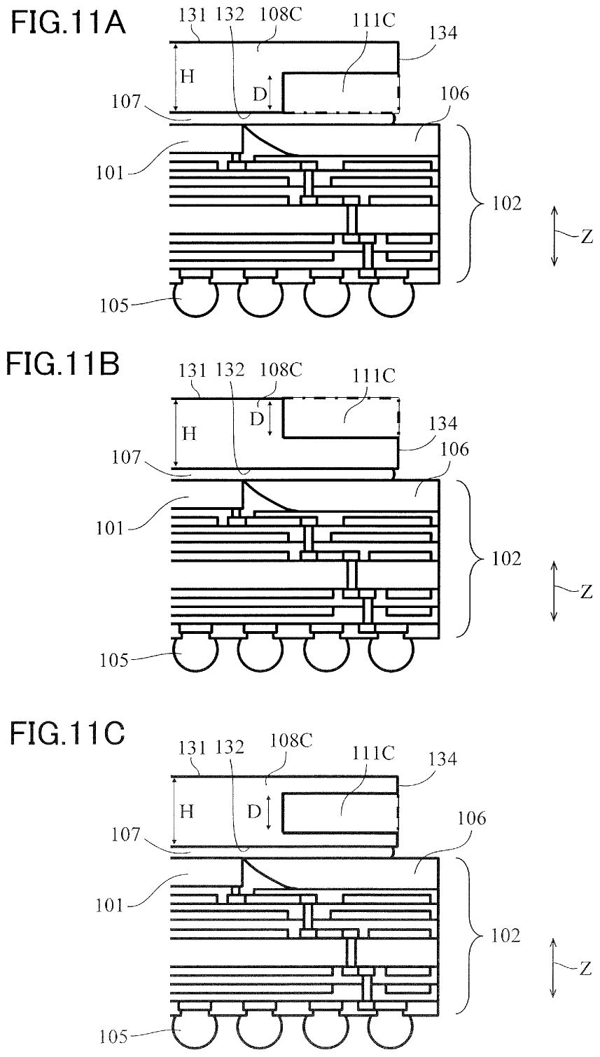

FIGS. 11A, 11B, and 11C are each a section view of the semiconductor device according to the third exemplary embodiment. As illustrated in FIG. 11A, the portion 111C is a recess portion opening on the main surface 131 side and an end surface 134 side. To be noted, the portion 111C may be a recess portion opening on the main surface 132 side and the end surface 134 side as illustrated in FIG. 11B, or a recess portion opening on the end surface 134 side as illustrated in FIG. 11C.

The thickness of the heat dissipating member 108C in the Z direction is represented by H, and the depth of the recess portion defined by the portion 111C in the Z direction is represented by D. The depth D of the recess portion defined by the portion 111C is smaller than the thickness H of the heat dissipating member 108C. The range of the depth D is preferably 0.1×H≤D≤0.9×H, and more preferably 0.5×H≤D≤0.9×H. Since the portion 111C is a portion that defines a recess portion as described above, the path of a return current generated in the heat dissipating member 108C in correspondence with a current flowing in a pattern of the wiring board 102 can be secured, and thus electromagnetic noise radiated from the heat dissipating member 108C can be reduced. The same applies to the portions 112C to 114C.

As described above, the warpage of the semiconductor device 100C can be reduced while securing a good heat dissipating property also in the case where the portions 111C to 114C are each a recess portion defined in a main surface and/or an end surface of the heat dissipating member.

As viewed in the Z direction, the portions 111C to 114C do not extend to the first region R1 and extend in only the second region R2. When a current flows in a circuit in the semiconductor element 101, a return current is generated in a portion of the region R1 opposing the semiconductor element 101 in the heat dissipating member 108C. Since the portions 111C to 114C each defining a slit are not present in the region R1, a path for the return current can be secured, and radiation of an electromagnetic noise can be reduced.

When the heat dissipating member 108C is viewed in the Z direction, the center of a surrounded region R140C surrounded by the shortest surrounding line 140C that surrounds the heat dissipating member 108C is denoted by B. The portions 111C to 114C extend in respective directions A1, A2, A3, and A4 from the center B toward the surrounding line 140C. As a result of this, the warpage of the semiconductor device 100C can be effectively reduced while securing a good heat dissipating property. To be noted, as viewed in the Z direction, the surrounding line 140C coincides with the outer peripheral edge 133C of the heat dissipating member 108C.

### Fourth Exemplary Embodiment

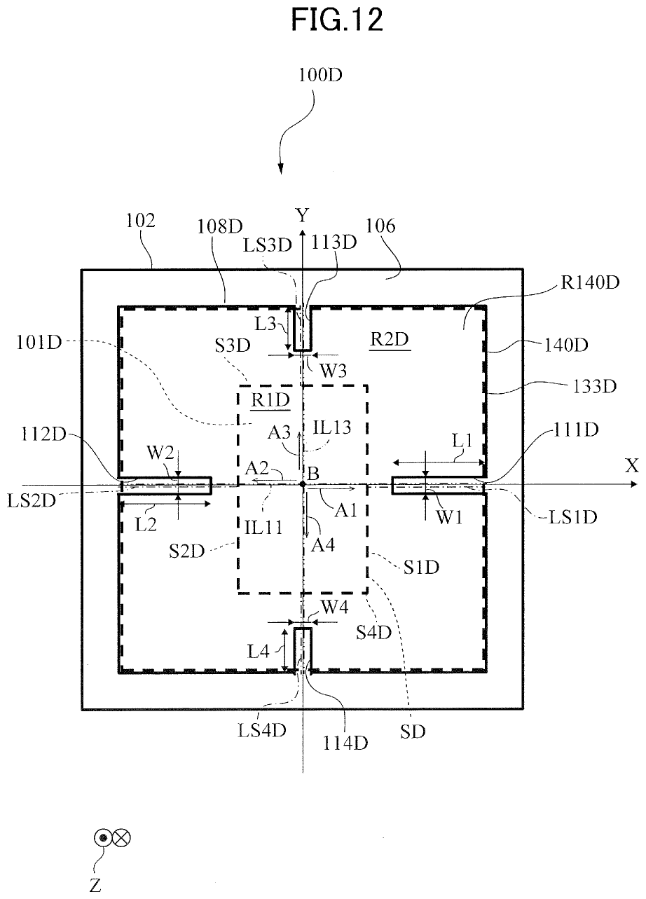

A semiconductor device of a fourth exemplary embodiment will be described. FIG. 12 is a plan view of a semiconductor device 100D according to the fourth exemplary embodiment. To be noted, the same elements as in the exemplary embodiments described above will be denoted by the same reference signs and detailed description thereof will be omitted.

The semiconductor device 100D includes the wiring board 102, a heat dissipating member 108D, and a semiconductor element 101D disposed between the wiring board 102 and the heat dissipating member 108D. The semiconductor element 101D is mounted on the wiring board 102, and is covered with the mold resin 106 with an upper surface thereof exposed. The heat dissipating member 108D is fixed to the upper surface of the semiconductor element 101D and the upper surface of the mold resin 106 via an adhesive layer. Although a case where the outer periphery of the semiconductor element 101 has a square shape as viewed in the Z direction has been described in the first to third exemplary embodiments, the outer periphery of the semiconductor element 101D has a rectangular shape as viewed in the Z direction in the fourth exemplary embodiment.

When the heat dissipating member 108D is viewed in the Z direction, the heat dissipating member 108D can be divided into a first region R1D that overlaps with the semiconductor element 101D, and a second region R2D that is further on the outside than the first region R1D and does not overlap with the semiconductor element 101D. As viewed in the Z direction, an outer periphery SD of the first region R1D has a quadrilateral shape, which is a rectangular shape in the present exemplary embodiment. In FIG. 12, the center of the first region R1D overlaps with the center of the wiring board 102. The outer periphery SD includes a long side S1D serving as a first side, a long side S2D serving as a second side and opposing the long side S1D, a short side S3D serving as a third side and adjacent to the long side S1D and the long side S2D, and a short side S4D serving as a fourth side, adjacent to the long side S1D and the long side S2D, and opposing the short side S3D. The outer peripheral edge 133D of the heat dissipating member 108D serving as the outer periphery of the second region R2D as viewed in the Z direction has a quadrilateral shape, which is a square shape in the present exemplary embodiment, larger than the outer periphery SD. In the present exemplary embodiment, sides of the outer periphery of the first region R1D are approximately parallel to the sides of the outer peripheral edge 133D of the heat dissipating member 108D.

The heat dissipating member 108D includes a first portion 111D that defines a slit or a recess portion, a second portion 112D that defines a slit or a recess portion, a third portion 113D that defines a slit or a recess portion, and a fourth portion 114D that defines a slit or a recess portion. The portions 111D to 114D are independent from one another. The portions 111D to 114D are each a portion that defines an empty space where the metal material making up the heat dissipating member 108D is not present. In the present exemplary embodiment, the portions 111D to 114D are each a portion that defines a slit. The portions 111D to 114D may be continuous or not continuous with the outer peripheral edge 133D of the heat dissipating member 108D. In the present exemplary embodiment, the portions 111D to 114D are continuous with the outer peripheral edge 133D. That is, the portions 111D to 114D extend to the outer peripheral edge 133D. As viewed in the Z direction, part or the entirety of the first portion 111D, the entirety in the present exemplary embodiment, is positioned in the region R2D. As viewed in the Z direction, part or the entirety of the second portion 112D, the entirety in the present exemplary embodiment, is positioned in the region R2D. As viewed in the Z direction, part or the entirety of the third portion 113D, the entirety in the present exemplary embodiment, is positioned in the region R2D. As viewed in the Z direction, part or the entirety of the fourth portion 114D, the entirety in the present exemplary embodiment, is positioned in the region R2D.

As viewed in the Z direction, the portions 111D to 114D do not extend in the first region R1D and only extend in the second region R2D. When a current flows in a circuit in the semiconductor element 101D, a return current is generated in a portion of the region R1D opposing the semiconductor element 101D in the heat dissipating member 108D. Since the portions 111D to 114D that each defines a slit are not present in the region R1D, a path for the return current can be secured, and thus radiation of an electromagnetic noise can be reduced.

As viewed in the Z direction, the first portion 111D extends along a first virtual line segment LS1D extending from the long side S1D of the outer periphery SD of the first region R1D toward the outside of the first region R1D. In addition, as viewed in the Z direction, the second portion 112D extends along a second virtual line segment LS2D extending from the long side S2D of the outer periphery SD of the first region R1D toward the outside of the first region R1D.

As viewed in the Z direction, the slit defined by the first portion 111D is positioned on a virtual straight line IL11 passing through the long side S1D of the outer periphery SD of the first region R1D and extending from the outer peripheral edge 133D of the heat dissipating member 108D to the inside of the first region R1D. The virtual straight line IL11 is also a virtual straight line passing through the long side S2D of the outer periphery SD of the first region R1D and extending to the inside of the first region R1D. As viewed in the Z direction, the slit defined by the second portion 112D is positioned on the virtual straight line IL11. That is, as viewed in the Z direction, the first portion 111D and the second portion 112D are positioned on one straight line, that is, the same virtual straight line IL11.

As viewed in the Z direction, the third portion 113D extends along a third virtual line segment LS3D extending from the short side S3D of the outer periphery SD of the first region R1D toward the outside of the first region R1D. In addition, as viewed in the Z direction, the fourth portion 114D extends along a fourth virtual line segment LS4D extending from the short side S4D of the outer periphery SD of the first region R1D toward the outside of the first region R1D.

As viewed in the Z direction, the slit defined by the third portion 113D is positioned on a virtual straight line IL13 passing through the short side S3D of the outer periphery SD of the first region R1D and extending from the outer peripheral edge 133D of the heat dissipating member 108D to the inside of the first region R1D. The virtual straight line IL13 is also a virtual straight line passing through the short side S4D of the outer periphery SD of the first region R1D and extending to the inside of the first region R1D. As viewed in the Z direction, the slit defined by the fourth portion 114D is positioned on the virtual straight line IL13. That is, as viewed in the Z direction, the third portion 113D and the fourth portion 114D are positioned on one straight line, that is, the same virtual straight line IL13.

A length W1 of the first portion 111D in a direction parallel to the long side S1D is equal to or smaller than a length L1 thereof in a direction perpendicular to the long side S1D, that is, W1≤L1 holds. A length W2 of the second portion 112D in a direction parallel to the long side S2D is equal to or smaller than a length L2 thereof in a direction perpendicular to the long side S2D, that is, W2≤L2 holds. A length W3 of the third portion 113D in a direction parallel to the short side S3D is equal to or smaller than a length L3 thereof in a direction perpendicular to the short side S3D, that is, W3≤L3 holds. A length W4 of the fourth portion 114D in a direction parallel to the short side S4D is equal to or smaller than a length L4 thereof in a direction perpendicular to the short side S4D, that is, W4≤L4 holds. In the present exemplary embodiment, W1=W2=W3=W4, L1>L3, L2>L4, L1=L2, and L3=L4 hold. That is, the lengths L1 and L2 of the first portion 111D and the second portion 112D are larger than the lengths L3 and L4 of the third portion 113D and the fourth portion 114D. As a result of this, the warpage of the semiconductor device 100D can be effectively reduced also in the case where the semiconductor element 101D has a rectangular shape as viewed in the Z direction.

As viewed in the Z direction, the portions 111D to 114D do not extend to the first region R1D and extend in only the second region R2D. When a current flows in a circuit in the semiconductor element 101D, a return current is generated in a portion of the region R1D opposing the semiconductor element 101D in the heat dissipating member 108D. Since the portions 111D to 114D each defining a slit are not present in the region R1D, a path for the return current can be secured, and radiation of an electromagnetic noise can be reduced.

When the heat dissipating member 108D is viewed in the Z direction, the center of a surrounded region R140D surrounded by the shortest surrounding line 140D that surrounds the heat dissipating member 108D is denoted by B. The portions 111D to 114D extend in respective directions A1, A2, A3, and A4 from the center B toward the surrounding line 140D. As a result of this, the warpage of the semiconductor device 100D can be effectively reduced while securing a good heat dissipating property. To be noted, as viewed in the Z direction, the surrounding line 140D coincides with the outer peripheral edge 133D of the heat dissipating member 108D.

To be noted, the portions 111D to 114D may each define a recess portion instead of a slit as in the third exemplary embodiment. In addition, the portions 111D to 114D may be each configured as modification examples described in the first exemplary embodiment and illustrated in FIGS. 4A to 5E.

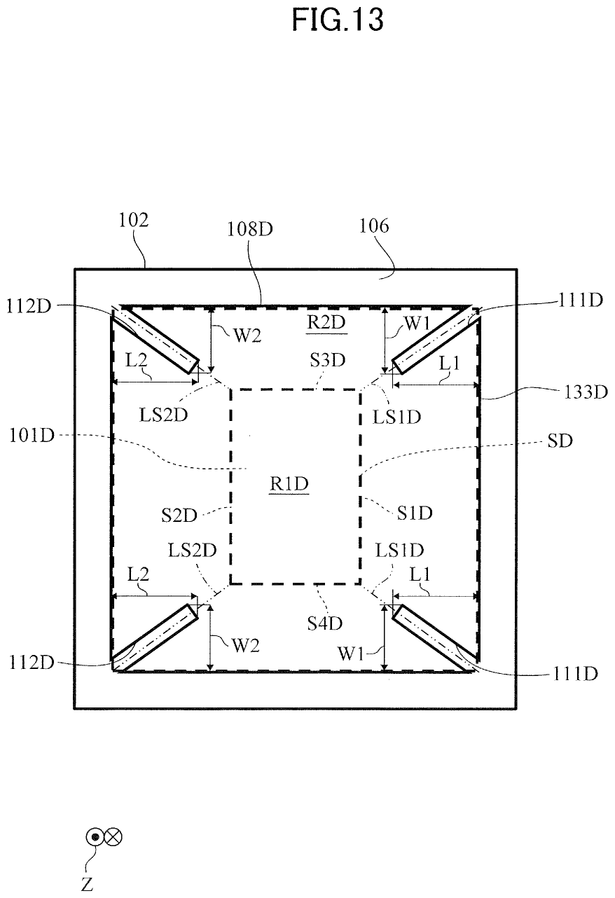

FIG. 13 is a plan view of yet another modification example of a semiconductor device. The first portion 111D may be disposed along the first virtual line segment LS1D extending from the long side S1D to the outside of the first region R1D. In this case, the first virtual line segment LS1D does not have to be perpendicular to the long side S1D as illustrated in FIG. 13. Similarly, the second portion 112D may be disposed along the second virtual line segment LS2D extending from the long side S2D to the outside of the first region R1D. In this case, the second virtual line segment LS2D does not have to be perpendicular to the long side S2D as illustrated in FIG. 13. To be noted, in the case where a portion that defines a slit or a recess portion is positioned on a virtual line segment intersecting with a corner portion between the long side S1D and the short side S3D or the short side S4D, the portion is referred to as the first portion 111D with reference to the long side S1D. Similarly, in the case where a portion that defines a slit or a recess portion is positioned on a virtual line segment intersecting with a corner portion between the long side S2D and the short side S3D or the short side S4D, the portion is referred to as the second portion 112D with reference to the long side S2D. Therefore, in the example of FIG. 13, two first portions 111D satisfying W1≤L1 and two second portions 112D satisfying W2≤L2 are present.

### Fifth Exemplary Embodiment

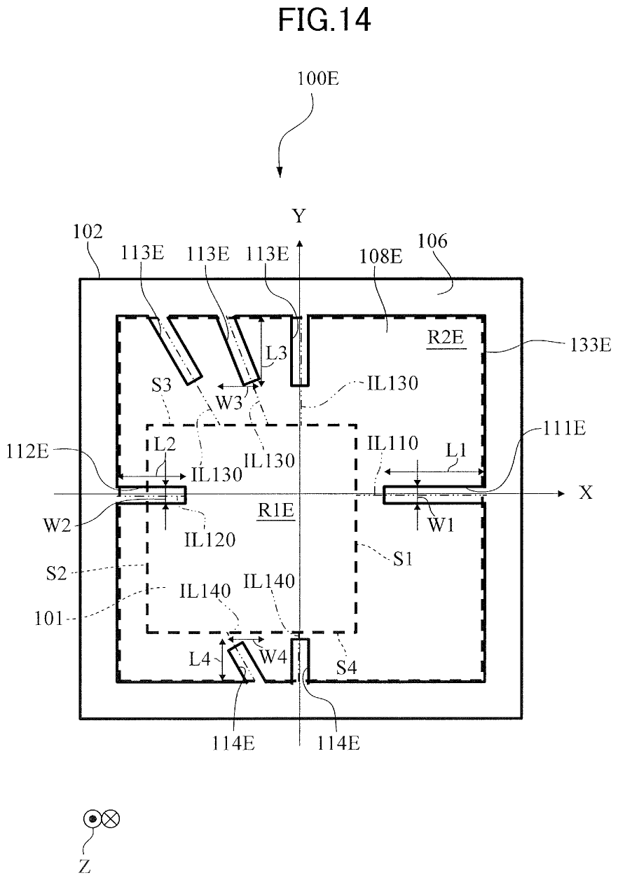

A semiconductor device of a fifth exemplary embodiment will be described. FIG. 14 is a plan view of a semiconductor device 100E according to the fifth exemplary embodiment. To be noted, the same elements as in the exemplary embodiments described above will be denoted by the same reference signs and detailed description thereof will be omitted.

The semiconductor device 100E includes the wiring board 102, a heat dissipating member 108E, and the semiconductor element 101 disposed between the wiring board 102 and the heat dissipating member 108E. The semiconductor element 101 is mounted on the wiring board 102, and is covered by the mold resin 106 with an upper surface thereof exposed. The heat dissipating member 108E is fixed to the upper surface of the semiconductor element 101 and the upper surface of the mold resin 106 via an adhesive layer. The heat dissipating member 108E can be divided into a first region R1E that overlaps with the semiconductor element 101 and a second region R2E that is further on the outside than the first region R1E and does not overlap with the semiconductor element 101.

Although a case where the center of the semiconductor element overlaps with the center of the wiring board 102 as viewed in the Z direction has been described in the first to fourth exemplary embodiments, in the fifth exemplary embodiment, the center of the semiconductor element 101, that is, the center of the first region R1E is deviated from the center of the wiring board 102 as viewed in the Z direction. In the case where the center of the semiconductor element 101 is deviated from the center of the wiring board 102 in the X direction and in the Y direction, magnitudes of the thermal stress in the X direction, the thermal stress in the −X direction, the thermal stress in the Y direction, and the thermal stress in the −Y direction applied to the heat dissipating member are different from one another.

The heat dissipating member 108E includes a first portion 111E, a second portion 112E, a third portion 113E, and a fourth portion 114E which each defines a slit or a recess portion and part or entirety of which is positioned in the second region R2E as viewed in the Z direction. The portions 111E to 114E are independent from one another. In the present exemplary embodiment, the difference in the thermal stress is compensated by adjusting the numbers and shapes of the first portion 111E, the second portion 112E, the third portion 113E, and the fourth portion 114E. For example, in the example of FIG. 14, the heat dissipating member 108E includes one first portion 111E, one second portion 112E, three third portions 113E, and two fourth portions 114E. Further, the length of each portion defining an empty space in the direction in which the portion extends is adjusted. It is preferable that the portions 111E to 114E extend to and are continuous with an outer peripheral edge 133E of the heat dissipating member 108E as viewed in the Z direction similarly to the first exemplary embodiment. In addition, the portions 111E to 114E may satisfy W1≤L1, W2≤L2, W3≤L3, and W4≤L4 similarly to the first exemplary embodiment. The portions 111E to 114E preferably satisfy W1<L1, W2<L2, W3<L3, and W4<L4.

The first portion 111E is disposed along a virtual line segment IL110 extending from the first side S1 toward the outside of the first region R1E. The second portion 112E is disposed along a virtual line segment IL120 extending from the second side S2 toward the outside of the first region R1E. The third portions 113E are disposed along virtual line segments IL130 extending from the third side S3 toward the outside of the first region R1E. The fourth portions 114E are disposed along virtual line segments IL140 extending from the fourth side S4 toward the outside of the first region R1E. The virtual line segments IL110 to IL140 are virtual line segments extending from the first region R1E to the outside toward the outer peripheral edge 133E of the heat dissipating member 108E as viewed in the Z direction.

The warpage of the semiconductor device 100E can be effectively reduced by adjusting the shapes and/or numbers of the portions that each defines a slit or a recess portion and are each formed in the heat dissipating member 108E, also in the case where the center of the semiconductor element 101 is deviated from the wiring board 102. To be noted, the warpage can be also effectively reduced in accordance with the same principle also in the case where a plurality of semiconductor elements are mounted on the wiring board 102.

The present invention is not limited to the exemplary embodiments described above, and can be modified in many ways within the technical concept of the present invention. In addition, the effects described in the exemplary embodiments are merely enumeration of the most preferable effects that can be achieved by the present invention, and the effects of the present invention are not limited to those described in the exemplary embodiments.

Although a case where the semiconductor device is a semiconductor package of BGA has been described in the exemplary embodiments described above, the configuration is not limited to this, and the present invention can be applied to various semiconductor packages including a heat dissipating member.

Although a case where a digital camera that is an image pickup apparatus is an example of an electronic device has been described in the exemplary embodiments described above, the configuration is not limited to this. For example, the image pickup apparatus may be a mobile terminal such as a smartphone. In addition, the electronic device may be a device different from the image pickup apparatus and may be, for example, an image forming apparatus such as a printer.

In addition, although a case where the outer peripheral edge of the heat dissipating member has a quadrilateral shape as viewed in the Z direction has been described in the exemplary embodiments described above, the configuration is not limited to this, and the outer peripheral edge may have an arbitrary shape. For example, the outer peripheral edge of the heat dissipating member as viewed in the Z direction may be a polygonal shape different from a quadrilateral shape, a circular shape, or an elliptical shape.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-148903, filed Aug. 7, 2018, and Japanese Patent Application No. 2019-132188, filed Jul. 17, 2019, which are hereby incorporated by reference herein in their entirety.

What is claimed is:

1. A semiconductor device comprising:
a rigid substrate;
a plate-like heat dissipating member; and
a semiconductor element provided between the rigid substrate and the heat dissipating member and mounted on the rigid substrate,
wherein the heat dissipating member comprises a first portion that defines a slit or a recess portion, and
wherein the first portion extends along a first virtual line segment extending from a first side of an outer periphery of a first region that overlaps with the semiconductor element toward an outside of the first region as viewed in a direction perpendicular to a main surface of the heat dissipating member, and a length of the first portion in a direction parallel to the first side is equal to or smaller than a length of the first portion in a direction perpendicular to the first side.

2. The semiconductor device according to claim 1, wherein the first portion extends to an outer peripheral edge of the heat dissipating member as viewed in the direction perpendicular to the main surface.

3. The semiconductor device according to claim 1,
wherein the heat dissipating member comprises a second portion that defines a slit or a recess portion and that is independent from the first portion, and
wherein the second portion extends along a second virtual line segment extending from a second side opposing the first side in the outer periphery of the first region toward the outside of the first region as viewed in the direction perpendicular to the main surface, and a length of the second portion in a direction parallel to the second side is equal to or smaller than a length of the second portion in a direction perpendicular to the second side.

4. The semiconductor device according to claim 3, wherein the second portion extends to an outer peripheral edge of the heat dissipating member as viewed in the direction perpendicular to the main surface.

5. The semiconductor device according to claim 3, wherein the first portion and the second portion are arranged on one straight line as viewed in the direction perpendicular to the main surface.

6. The semiconductor device according to claim 3,
wherein the heat dissipating member comprises a third portion that defines a slit or a recess portion and that is independent from the first portion and the second portion, and
wherein the third portion extends along a third virtual line segment extending from a third side adjacent to the first side in the outer periphery of the first region toward the outside of the first region as viewed in the direction perpendicular to the main surface, and a length of the third portion in a direction parallel to the third side is equal to or smaller than a length of the third portion in a direction perpendicular to the third side.

7. The semiconductor device according to claim 6, wherein the third portion extends to an outer peripheral edge of the heat dissipating member as viewed in the direction perpendicular to the main surface.

8. The semiconductor device according to claim 6,
wherein the heat dissipating member comprises a fourth portion that defines a slit or a recess portion and that is independent from the first portion, the second portion, and the third portion, and
wherein the fourth portion extends along a fourth virtual line segment extending from a fourth side opposing the third side in the outer periphery of the first region toward the outside of the first region as viewed in the direction perpendicular to the main surface, and a length of the fourth portion in a direction parallel to the fourth side is equal to or smaller than a length of the fourth portion in a direction perpendicular to the fourth side.

9. The semiconductor device according to claim 8, wherein the fourth portion is extends to an outer peripheral edge of the heat dissipating member as viewed in the direction perpendicular to the main surface.

10. The semiconductor device according to claim 8, wherein the third portion and the fourth portion are arranged on one straight line as viewed in the direction perpendicular to the main surface.

11. The semiconductor device according to claim 8, wherein the first portion, the second portion, the third portion, and the fourth portion extend in directions from a center of a surrounded region surrounded by a shortest surrounding line surrounding the heat dissipating member toward the surrounding line as viewed in the direction perpendicular to the main surface.

12. The semiconductor device according to claim 8, wherein the first portion, the second portion, the third portion, and the fourth portion do not extend in the first region.

13. The semiconductor device according to claim 1,
wherein the semiconductor element comprises an image processing circuit and an interface circuit, and
wherein the first portion does not overlap with the image processing circuit and the interface circuit as viewed in the direction perpendicular to the main surface.

14. The semiconductor device according to claim 3,
wherein the semiconductor element comprises an image processing circuit and an interface circuit, and
wherein the second portion does not overlap with the image processing circuit and the interface circuit as viewed in the direction perpendicular to the main surface.

15. The semiconductor device according to claim 6,
wherein the semiconductor element comprises an image processing circuit and an interface circuit, and
wherein the third portion does not overlap with the image processing circuit and the interface circuit as viewed in the direction perpendicular to the main surface.

16. The semiconductor device according to claim 8,
wherein the semiconductor element comprises an image processing circuit and an interface circuit, and
wherein the fourth portion does not overlap with the image processing circuit and the interface circuit as viewed in the direction perpendicular to the main surface.

17. The semiconductor device according to claim 1, wherein an adhesive layer is formed between the heat dissipating member and the semiconductor element.

18. A printed circuit board comprising:
the semiconductor device according to claim 1; and
a printed wiring board on which the semiconductor device is mounted.

19. An electronic device comprising:
a casing; and
the printed circuit board according to claim 18 disposed inside the casing.

20. An image pickup apparatus comprising:
a casing;
the printed circuit board according to claim 18 disposed inside the casing; and
an image pickup element disposed inside the casing.
